(19) United States
(12) Patent Application Publication
(10) Pub. No.: US 2026/0169932 A1
(43) Pub. Date: Jun. 18, 2026

(54) GRAY CODING MECHANISM TO REDUCE METAL USAGE

(71) Applicant: NVIDIA Corp., Santa Clara, CA (US)

(72) Inventors: Lei Wang, San Jose, CA (US); Chen Lu, San Jose, CA (US); Zhenye Jiang, Cupertino, CA (US); Haiyan Gong, Sunnyvale, CA (US); Hwong-Kwo Lin, Palo Alto, CA (US)

(73) Assignee: NVIDIA Corp., Santa Clara, CA (US)

(21) Appl. No.: 18/981,198

(22) Filed: Dec. 13, 2024

(51) Int. Cl. G06F 13/16; G06F 13/40; H03M 7/16

(52) U.S. Cl. CPC G06F 13/16; G06F 13/40; H03M 7/16

(57) ABSTRACT

Metal track reduction mechanisms in systems utilizing an address bus wherein an address decoder is configured to operate on a first subset of applied address bits and a Gray Coder is configured to operate on a second subset of the applied address bits to generate a Gray Code. A sequence of inverters is configured to invert a bit of the Gray Code at multiple locations along the address bus, each location corresponding to a component to select with the applied address.

### BACKGROUND

Memory devices may include repair features to improve their manufacturing yield. One type of repair feature involves manufacturing the memory device to include spare columns. During quality testing a defective column may be identified. A repair address may be configured for the defective column, remapping the addresses of memory locations in the defective column to a non-defective column.

The decoding of addresses for remapped memory locations may be carried out in two stages: pre-decoding and final-decoding. The pre-decoded address signals are carried on metal tracks that may congest the routing of other memory metal tracks, e.g., data paths.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts aspects of a machine memory system in one embodiment.

FIG. 2 depicts additional aspects of a machine memory system in one embodiment.

FIG. 3 depicts additional aspects of a machine memory system in one embodiment.

FIG. 4 depicts an example of addressing logic for of a memory system.

FIG. 5 depicts aspects of a memory system in an exemplary embodiment.

FIG. 6 depicts aspects of a memory system in an exemplary embodiment with reduced metal track utilization.

FIG. 7 illustrates an aspect of the subject matter in accordance with one embodiment.

### DETAILED DESCRIPTION

Mechanisms are disclosed herein to utilize a Gray Code scheme to reduce the metal track usage in memory devices. A Gray Code counter is utilized to propagate an input address for operating on the memory. In a Gray Code sequence of binary numbers the adjacent numbers have only a single bit difference. Leveraging this feature of Gray Code sequences enables the use of a single inverter at each stage to implement the counting. An input address is selected once the count matches a particular Gray Code value, e.g., zero.

The disclosed mechanisms may be utilized, for example, in Static Random-Access Memory (SRAM) or other memory devices. SRAM is a type of semiconductor memory that uses bi-stable latching circuitry to store each bit. SRAM retains data bits in its memory as long as power is being supplied. SRAM is generally faster and more reliable than dynamic RAM (DRAM) but it is also more expensive, making it suitable for applications such as cache memory.

A data path input/output (DPIO) address may be encoded to Gray Code, for example by a memory controller or preceding arrival at the memory controller. The Gray Code DPIO address is propagated along with a memory address location to each DPIO. The number of metal tracks needed to implement the address bus is therefore equal to the combined bit width of the DPIO address and memory location address. At each DPIO along the bus, if the DPIO address matches a Gray Code assigned to the DPIO, then that DPIO is selected for application of the memory address.

A single inverter may be added in each DPIO along an address bus to invert a particular bit of the applied Gray Code to update the Gray Code applied to the next DPIO along the bus. The sequence of bit inversion positions is configured the generate an evolving Gray Code value along the address bus.

By way of example, the lower four bits of a memory operation address may be Gray Coded as follows:

(0000,0001,0011,0010,0110,0111,0101,0100,1100,1101,1111,1110,1010,1011,1001,1000). The following sequence of bit inverting positions may be implemented in the DPIOs along the address bus to evolve the Gray Code propagating down the bus from 0000 to 1000 and back to 0000: (0,1,0,2,0,1,0,3,0,1,0,2,0,1,0,3).

This sequence may be implemented for sets of eight DPIOs as follows:

| | | | | | | | | |
|---|---|---|---|---|---|---|---|---|
| DPIO Slice | 8i | 8i + 1 | 8i + 2 | 8i + 3 | 8i + 4 | 8i + 5 | 8i + 6 | 8i + 7 |
| Index (i = 0 . . .) | | | | | | | | |
| Bit inverting | 0 | 1 | 0 | 2 | 0 | 1 | 0 | 3 |
| position | | | | | | | | |

A Gray Code sequence G0, G1, G2, . . . , Gn may be constructed to represent an address ranging in value from 0 to 2^{k}−1 (where n=2^{k}). A sequence S=(S0, S1, S2, . . . , Sn) may be configured to generate the Gray Code sequence from G0 to Gn and back to G0. In each step Si (i=0, . . . , n), exactly 1 bit is inverted. Starting from some number Gm, applying any sub-sequence of S won't generate Gm. In total, the sequence S flips each bit of an input value exactly twice. Therefore, for any starting-point Gray Code Gm, after applying S, Gm is obtained only once at the end of S.

Let Gm be the number generated by applying the sequence S0, S1, . . . , Sm-1 to the starting value G0. The remainder sequence Sm, . . . , Sn may then be applied to obtain Gm again. G0 will not be generated during the application of this remainder sequence. Thus, for an input address Gm, the value G0 is generated by the sequence S at position k*n+m, meaning the correct DPIO slices may always be selected.

The disclosed Gray Code may be utilized in memory devices that comprise redundancy repair. For an n-bit fuse set address, the disclosed mechanisms may be implemented to reduce a number of metal tracks (with one extra track possibly used to enable a memory repair mode). The extent of the reduction in the number of metal tracks depends on the DPIO design. For example, if the DPIO splits a 7-bit fuse set address into 2-to-4 tracks, 2-to-4 tracks, and 3-to-8 tracks for input to three pre-decoders, the disclosed mechanisms may save (4+4+8)-(7+1)=8 tracks. If the DPIO design fully decodes the 7 fuse set bits to 2⁷ tracks, the disclosed mechanisms may save 2⁷−(7+1) tracks.

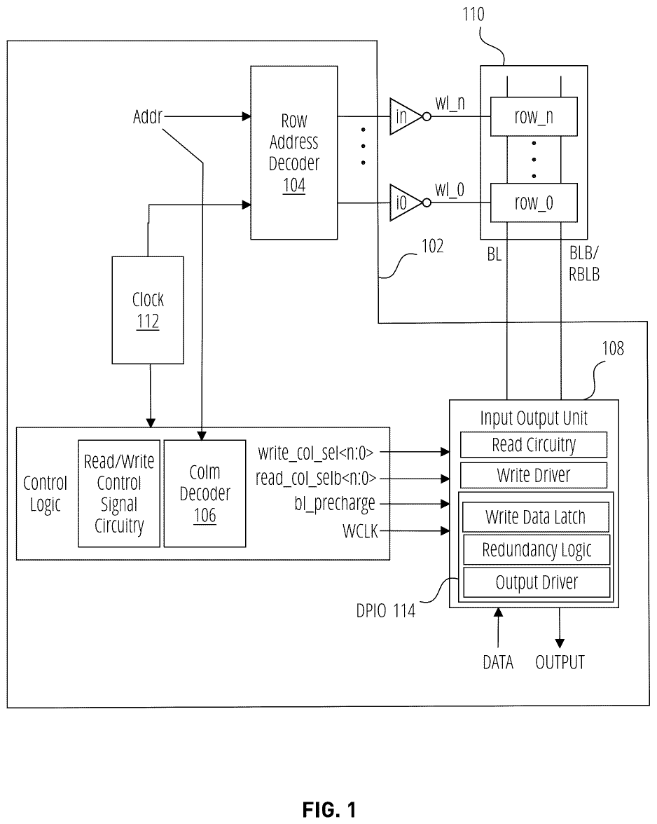

FIG. 1 depicts a memory controller 102 in one embodiment. A row address decoder 104 translates a memory address into a row (word line) selection, and a column decoder 106 translates the address into column (bitline) selection(s). The bit-storing cells along the selected row and column are read by the input output unit 108, which includes logic to process data read from the machine memory 110 and logic for writing values into the bit-storing cells of the machine memory 110. For example the input output unit 108 comprises DPIO 114 (comprising a write data latch, redundancy logic, and an output driver, among other things).

Operations by the memory controller 102 may be performed synchronously and thus coordinated by a clock 112.

It is common for some blocks of bit-storing cells in the main memory array to test as non-functional post-manufacture. These bad blocks may be disabled using switches and their memory addresses may be remapped onto functional redundant memory blocks manufactured into the memory device.

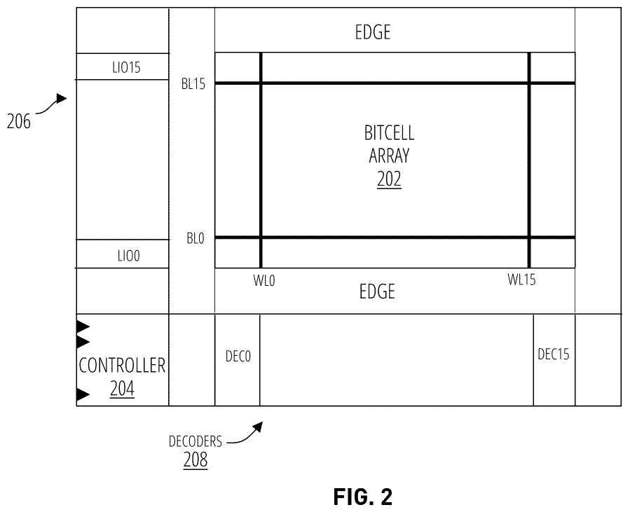

FIG. 2 depicts aspects of a machine memory in one embodiment. A bitcell array 202 is traversed by bitlines (BLx) and word lines (WLx). A controller 204 operates peripheral data path IO logic 206 (DPIOx) coupled to bitlines of the bitcell array 202 for addressing, reading, and writing to memory locations. Address decoders 208 (DECx) operate word lines that are also used to read and write data from and to the bitcell array 202.

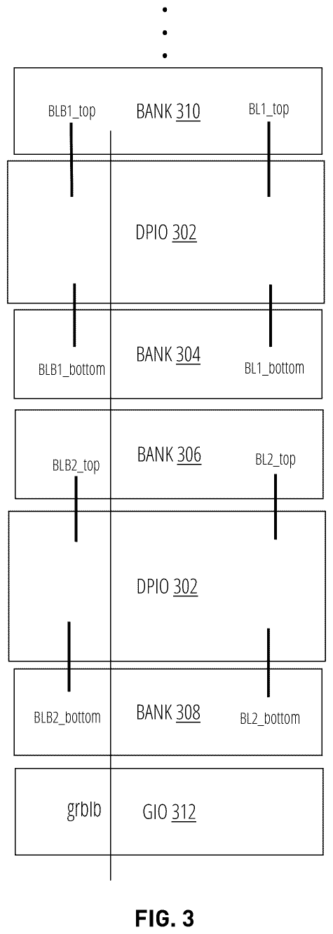

FIG. 3 depicts an example of a multi-bank memory system utilizing a plurality of data path IO stages 302 and local bit lines. The depicted example comprises memory banks 304, 306, 308, 310, but there may be more or fewer than this, depending on the implementation. In this example, each data path IO stage 302 operates on a bit line that is local to (does not extend beyond) a pair of the memory banks.

The data path IO stages 302 share common IO logic 312 (i.e., GIO). In some memory technologies, a local bit line may extend through more than two memory banks, but generally less than all of the memory banks in the memory. In some embodiments, such as where the memory system is a register file, a global read bit line grblb may extend from the memory controller (e.g., input output unit 108) to traverse the memory banks.

Address remapping mechanisms may be applied to substitute one memory block for another memory block and particularly may be used to substitute a non-defective memory block for a defective memory block within a memory device.

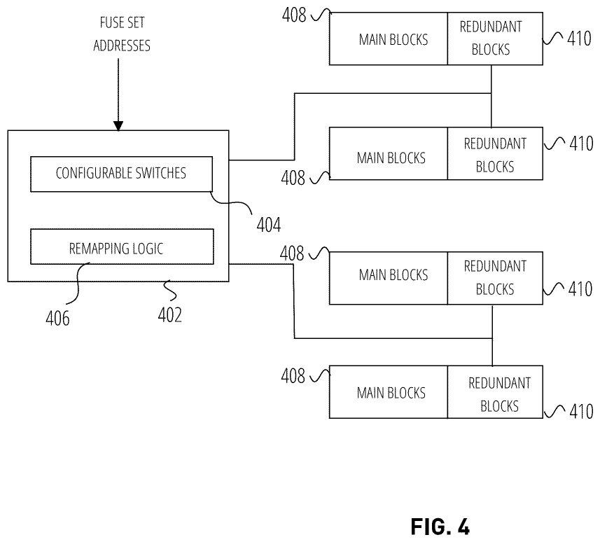

FIG. 4 depicts addressing logic 402 of a memory device at a high level, wherein configurable switches 404 are utilized to activate address remapping logic 406 for addresses of defective regions of main blocks 408 to functional regions of redundant blocks 410.

In one approach, when a defective main block is identified during a memory test, a corresponding “fuse set” address is applied to the address remapping logic 406. Corresponding ones of the configurable switches 404 are configured in response and the address is stored (e.g., in a latch).

During operation of the memory device, when an incoming address matches a programmed address configured in the switches and stored in the latches, the address comparator signals the address remapping logic 406 to select one of the redundant blocks in a given bank of the memory as a substitute for the defective main block in the same bank.

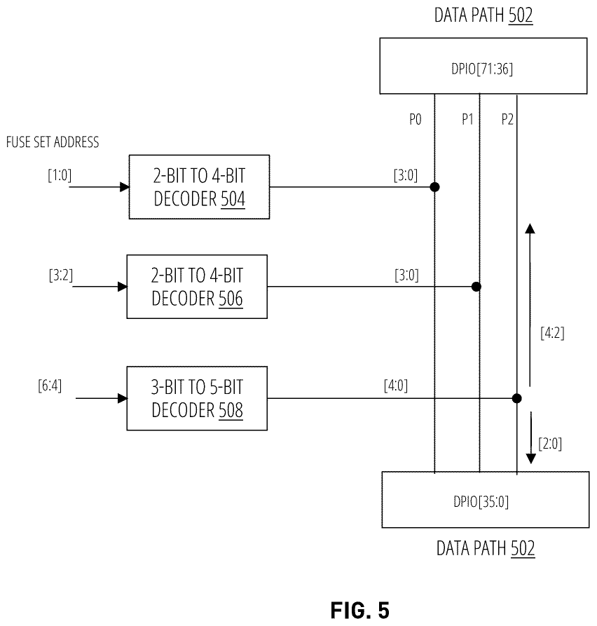

FIG. 5 depicts aspects of a memory system in an exemplary embodiment comprising a data path 502 with 72 DPIO stages. The DPIO stages are arranged along an address bus P comprising sub-sections P0, P1, and P2. The system comprises a 2-bit to 4-bit decoder 504, a 2-bit to 4-bit decoder 506, and a 3-bit to 5-bit decoder 508. A 7-bit fuse set address is decoded into a 13-bit address on the address bus (thereby requiring 13 metal tracks for the address bus).

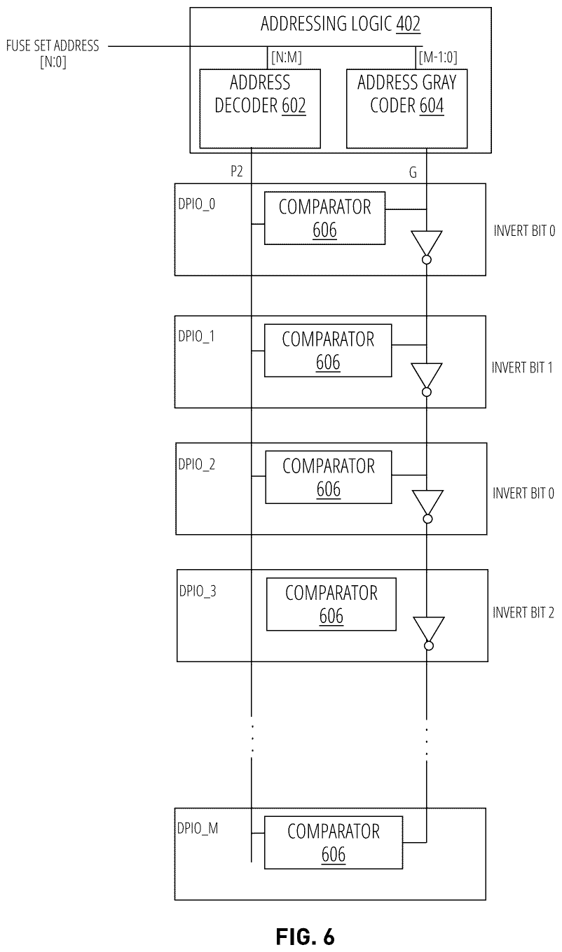

FIG. 6 depicts aspects of a memory system in an exemplary embodiment with reduced metal track utilization for the address bus of the DPIO stages. The addressing logic 402 comprises an address decoder 602 and an address Gray Coder 604. The address decoder 602 decodes N−M+1 bits of a fuse set address applied to the addressing logic 402 and applies the decoded bits to the DPIO stages on one portion P2 of the address bus. The address Gray Coder 604 encodes M bits of the fuse set address as a Gray Code on another portion G of the address bus.

For systems utilizing, for example, a 7-bit fuse set address with N=6 and M=4, the 3-bit address decoded onto P2 selects a group of eight DPIOs. The 4-bit Gray Code on portion G of the address bus selects one of the DPIOs in a group of eight. The total number of metal tracks for the address bus in this example is 5 tracks for the P2 bus and 4 tracks for the G bus, a total of 9 tracks, which is a reduction of 4 tracks from the 13 metal track implementation depicted in FIG. 5.

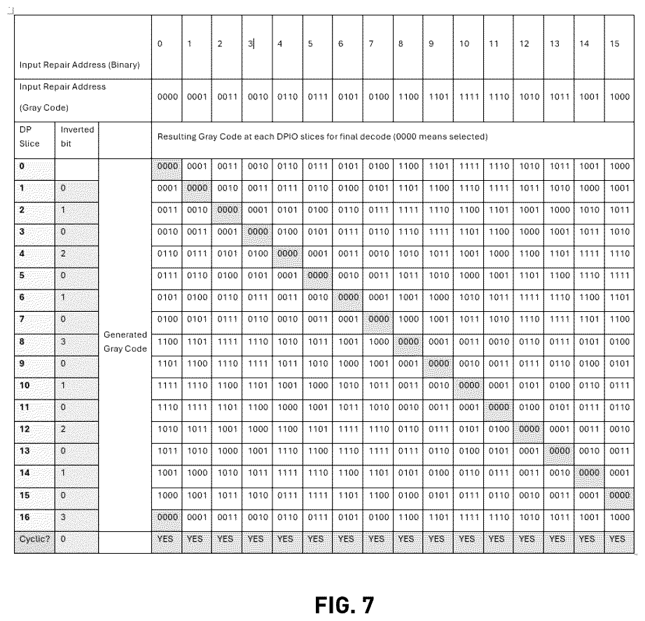

An inverter is associated with each DPIO stage to invert one bit of the Gray Code in the address bits on the G bus. At each stage a comparator 606 checks whether or not the address on the G bus has reached a configured value, e.g., all zeros. If a DPIO in the group selected by P2 detects a match with the preconfigured value, that DPIO is selected. A sequence of bit inversions applied at each DPIO stage for this example is depicted in the table below; the sequence repeats for each group of 8 DPIO stages along the address bus. FIG. 7 depicts an example of the sequence that may occur in one embodiment.

| DPIO | Inverted Bit of Gray Code |
|---|---|
| 0 | none |
| 1 | 0 |
| 2 | 1 |
| 3 | 0 |
| 4 | 2 |
| 5 | 0 |
| 6 | 1 |
| 7 | 0 |
| 8 | 3 |
| 9 | 0 |
| 10 | 1 |
| 11 | 0 |
| 12 | 2 |
| 13 | 0 |
| 14 | 1 |
| 15 | 0 |
| . . . | 3 |

The metal track reduction mechanisms disclosed herein have been described in conjunction with a machine memory implementation, and more particularly in conjunction with a memory repair implementation. However the disclosed mechanisms are generally applicable to reduce metal tracks in any system wherein a selection among various components is made via an applied multi-bit code. Generally, the disclosed mechanisms may be utilized in systems comprising a decoder configured to generate a first subset of selection bits on a bus, a Gray Coder configured to generate a Gray Code on the bus, and a sequence of inverters configured to invert a single bit of the Gray Code at each of a plurality of locations along the bus, each location corresponding to a component to select for an operation.

### LISTING OF DRAWING ELEMENTS

102 memory controller
104 row address decoder
106 column decoder
108 input output unit
110 machine memory
112 clock
114 DPIO
202 bitcell array
204 controller
206 data path IO logic
208 decoder
302 data path IO stage
304 bank
306 bank
308 bank
310 bank
312 common IO logic
402 addressing logic
404 configurable switches
406 address remapping logic
408 main block
410 redundant block
502 data path
504 2-bit to 4-bit decoder
506 2-bit to 4-bit decoder
508 3-bit to 5-bit decoder
602 address decoder
604 address Gray Coder
606 comparator

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation-[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112 (f) for that claim element. Accordingly, claims in this application that do not otherwise include the “means for” [performing a function] construct should not be interpreted under 35 U.S.C § 112 (f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the intended invention as claimed. The scope of inventive subject matter is not limited to the depicted embodiments but is rather set forth in the following Claims.

What is claimed is:

1. A machine memory comprising:
an address bus;
an address decoder configured to operate on a first subset of applied address bits;
a Gray Coder configured to operate on a second subset of the applied address bits to generate a Gray Code; and
a sequence of inverters configured to invert a bit of the Gray Code at multiple locations along the address bus, each location corresponding to a data path input-output stage (DPIO).

2. The machine memory of claim 1, wherein the applied address bits comprise a fuse set address.

3. The machine memory of claim 1, wherein the address bus is divided into a first section configured to receive an output of the address decoder and a second section configured to receive an output of the Gray Coder.

4. The machine memory of claim 3, wherein the first section of the address bus comprises five metal tracks and the section of the address bus comprises four metal tracks.

5. The machine memory of claim 1, each DPIO comprising a comparator configured to compare the Gray Code to a preconfigured value.

6. The machine memory of claim 5, wherein the preconfigured value comprises all zeros.

7. The machine memory of claim 5, wherein the sequence of inverters is configured such that the Gray Code generated by the Gray Coder repeats on the address bus for each group of N of the DPIOs, where N=2ⁿ−1 and n is a number of bits comprised by the Gray Code.

8. A system comprising:
a bus;
a decoder configured to generate a first subset of selection bits on the bus;
a Gray Coder configured to generate a Gray Code on the bus; and
a sequence of inverters configured to invert a single bit of the Gray Code at each of a plurality of locations along the bus, each location corresponding to a component to select for an operation.

9. The system of claim 8, wherein the decoder and the Gray Coder are configured to operate on an address for the component to select.

10. The system of claim 8, wherein the bus is divided into a first section configured to receive an output of the decoder and a second section configured to receive the Gray Code.

11. The system of claim 8, wherein the first selection bits consist of five bits and the Gray Code consists of four bits.

12. The system of claim 8, wherein each component to select comprising a comparator configured to compare the Gray Code to a preconfigured value.

13. The system of claim 12, wherein the preconfigured value comprises all zeros.

14. The system of claim 12, wherein the sequence of inverters is configured such that the Gray Code generated by the Gray Coder repeats on the bus for each group of N of the components to select, where N=2ⁿ−1 and n is a number of bits comprised by the Gray Code.

15. A method comprising:
operating a decoder to generate a first subset of selection bits on a bus;
operating a Gray Coder to generate a Gray Code on the bus; and
propagating the Gray Code through a sequence of inverters such that a single bit of the Gray Code in inverted at each of a plurality of locations along the bus, each location corresponding to a component to select for an operation.

16. The method of claim 15, further comprising:
applying a fuse set address to the decoder and the Gray Coder.

17. The method of claim 15, further comprising:
applying an output of the decoder to a first section of the bus and an output of the Gray Coder to a second section of the bus.

18. The method of claim 15, further comprising:
comparing the Gray Code to a preconfigured value at each component to select.

19. The method of claim 18, wherein the preconfigured value comprises all zeros.

20. The method of claim 18, wherein the sequence of inverters is configured such that the Gray Code generated by the Gray Coder repeats on the bus for each group of N of the components to select, where N=2ⁿ−1 and n is a number of bits comprised by the Gray Code.
